(19) United States
(12) Patent Application Publication
(10) Pub. No.: US 2026/0130135 A1
(43) Pub. Date: May 7, 2026

(54) GROWTH SUBSTRATE WAFER FOR HIGH-PERFORMANCE GAN SWITCHING POWER DEVICES, EPITAXY WAFER USING THE SAME, AND MANUFACTURING METHOD THEREOF

(71) Applicant: WAVELORD CO., LTD., Gyeonggi-do (KR)

(72) Inventors: June O SONG, Gyeonggi-do (KR); Jihyung MOON, Gyeonggi-do (KR); Younghun HAN, Gyeonggi-do (KR); Hyun Sun YUN, Gyeonggi-do (KR)

(21) Appl. No.: 19/378,953

(22) Filed: Nov. 4, 2025

(30) Foreign Application Priority Data
Nov. 5, 2024 (KR) 10-2024-0154847
Nov. 4, 2025 (KR) 10-2025-0163805

(51) Int. Cl. H01L 21/02; C30B 25/04; C30B 25/18; C30B 29/40; H10D 30/47

(52) U.S. Cl. CPC H10P 14/3416; C30B 25/04; C30B 25/183; C30B 29/403; C30B 29/406; H10P 14/2905; H10P 14/3216; H10P 14/3238; H10P 14/3256; H10D 30/471

(57) ABSTRACT

Embodiments according to the present invention provide a growth substrate wafer for high-performance GaN switching power devices, comprising: a Si growth substrate; a first AlN nucleation layer formed on the Si growth substrate; and a plurality of SiOx protrusions (Protrusion) discontinuously spaced apart and arranged on the first AlN nucleation layer, wherein the surface of the first AlN nucleation layer is exposed in the regions between the plurality of SiOx protrusions.

### CROSS-REFERENCE TO RELATED APPLICATIONS

This application claims the benefit and priority to Korean Patent Application Nos. 10-2024-0154847, filed on Nov. 5, 2024 and 10-2025-0163805, filed on Nov. 4, 2025. The entire disclosures of the applications identified in this paragraph are incorporated herein by references.

### FIELD

The present invention relates to a high-performance switching power device (Switching Power Device) using gallium nitride (GaN), and more particularly, to a patterned silicon substrate (PSiS, Patterned Si Substrate) for forming a high-quality GaN epitaxial layer on a silicon (Si) growth substrate, and an epitaxy wafer and manufacturing method thereof, which dramatically reduces the Threading Dislocation Density (TDD) using said substrate.

### BACKGROUND

Gallium nitride (GaN) compound semiconductor is a wide-bandgap material that has a higher breakdown field, excellent thermal conductivity, and high carrier mobility compared to conventional semiconductor materials such as silicon (Si) and gallium arsenide (GaAs).

Thanks to these characteristics, it can implement high power density in a smaller size and is drawing attention as a key material for next-generation power semiconductor devices.

For GaN power semiconductors to be competitive in the market, Normally-OFF operation with a high blocking voltage and low leakage current is essential.

The most ideal structure to implement this is a vertical structure device (Vertical FET) with a thick epitaxial region, but due to the difficulty in commercializing GaN homogenous growth substrates (GaN-on-GaN) and the low efficiency of the ion implantation process, horizontal structure High Electron Mobility Transistors (HEMTs) that grow a thin film on a heterogeneous growth substrate are currently mainly being manufactured.

At this time, heterogeneous growth substrates such as sapphire, silicon (Si), and silicon carbide (SiC) are used, but a very high threading dislocation density (TDD) on the level of 10⁷˜10¹⁰/cm² occurs due to the lattice constant and thermal expansion coefficient mismatch between the GaN epitaxial layer and the growth substrate. These threading dislocations are a persistent problem that critically and adversely affects device performance and reliability. Specifically, threading dislocations cause various problems as follows.
(1) Increased Leakage Current: Threading dislocations containing screw components (Screw and Mixed Dislocations) act as major leakage paths, degrading the device's Off-state characteristics.
(2) Reduced Blocking Voltage: Threading dislocations act as ‘hotspots’ that cause Electric Field Crowding at specific points within the device, leading to Premature Breakdown before the device reaches its inherent breakdown voltage.
(3) Decreased Switching Frequency: Threading dislocations act as scattering and trapping centers in the electron's movement path, reducing carrier mobility. This performance degradation is particularly prominent in horizontal HEMT structures where current flows laterally to the threading dislocations.
(4) Increased Dynamic On-resistance (RON): During high-voltage switching operation, charge is trapped in defects, including threading dislocations, and then slowly released, causing a phenomenon where the on-resistance temporarily increases immediately after the switch is turned on. This is a major cause of increased power loss.
(5) Decreased Reliability: Crystal defects such as threading dislocations become the starting point for various degradation mechanisms such as gate edge degradation, hot electron generation, and thin-film delamination when the device operates in high electric field and temperature environments, thereby shortening the device's lifespan.

Therefore, to commercialize high-performance, high-reliability GaN power devices, the development of high-quality epitaxial growth technology capable of controlling TDD to less than 10⁸/cm² on large-diameter 8-inch or 12-inch Si substrates is urgently required.

### SUMMARY

### Technical Problem

The present invention was devised to solve the problems of the conventional art as described above, and its main object is to solve the high threading dislocation density (TDD) problem that occurs when growing a GaN epitaxial layer on a large-diameter silicon (Si) growth substrate.

Specifically, an object of the present invention is to dramatically reduce TDD to less than 10⁸/cm² to provide a high-quality GaN HEMT epitaxy wafer that can improve electrical characteristics such as leakage current and dynamic ON-resistance, and enhance breakdown voltage and reliability.

Furthermore, another object of the present invention is to provide a growth substrate wafer for high-performance GaN power devices and a manufacturing method thereof, which is applicable to 8-inch and 12-inch large-diameter wafer processes, offering high productivity and cost-effectiveness.

### Technical Solution

Embodiments according to the present invention provide a growth substrate wafer for high-performance GaN switching power devices, comprising: a Si (111) growth substrate; a first AlN nucleation layer formed on the Si (111) growth substrate; and a plurality of SiOx protrusions discontinuously spaced apart and arranged on the first AlN nucleation layer, wherein the surface of the first AlN nucleation layer is exposed in the regions between the plurality of SiOx protrusions.

Herein, the shape of the SiOx protrusions is characterized by being a Lens, Truncated, Dome, Cone, Polygon, or Cubic shape.

Furthermore, it is characterized by further comprising a SiNx protective film formed between the first AlN nucleation layer and the plurality of SiOx protrusions.

Embodiments according to the present invention provide an epitaxy wafer using the growth substrate wafer, comprising: the growth substrate wafer; a GaN-based merged growth layer grown from the exposed surface of the first AlN nucleation layer between the plurality of SiOx protrusions, covering the top of the SiOx protrusions and merging with each other; and a GaN HEMT device active layer formed on the GaN-based merged growth layer.

Herein, the GaN-based merged growth layer may be provided as a single layer of undoped GaN (uGaN).

Alternatively, the GaN-based merged growth layer may be provided as a multilayer structure in which uGaN layers and AlN layers or AlGaN layers are alternately stacked.

Meanwhile, it may further comprise an Al(z)Ga(1-z)N stress control layer formed between the GaN-based merged growth layer and the GaN HEMT device active layer.

Furthermore, it may further comprise a second AlN nucleation layer formed between the plurality of SiOx protrusions and the GaN-based merged growth layer, covering the exposed surface of the first AlN nucleation layer and the surface of the SiOx protrusions.

Embodiments according to the present invention provide a method for manufacturing an epitaxy wafer, comprising the steps of: (a) preparing a Si (111) growth substrate; (b) forming a first AlN nucleation layer on the Si (111) growth substrate; (c) depositing a SiOx thin film on the first AlN nucleation layer; (d) patterning the SiOx thin film to form a plurality of discontinuously spaced SiOx protrusions; (e) forming a GaN-based merged growth layer by laterally growing (Epitaxial Lateral Overgrowth, ELOG) a GaN-based material from the first AlN nucleation layer exposed between the SiOx protrusions and merging them over the SiOx protrusions; and (f) stacking a GaN HEMT (High Electron Mobility Transistor) device active layer on the GaN-based merged growth layer.

Herein, said step (e) may involve forming the GaN-based merged growth layer by alternately and repeatedly growing uGaN layer and one of AlN layer and AlGaN layer.

Meanwhile, the method may further comprise a step of forming a second AlN nucleation layer on the first AlN nucleation layer and the plurality of SiOx protrusions, between said step (d) and step (e).

### Advantageous Effects

According to the present invention, the following effects can be obtained.

First, by using the ELOG method with the SiOx protrusion pattern formed on the Si (111) growth substrate, the propagation of threading dislocations, which arise from lattice mismatch with the Si substrate, to the upper device active layer can be effectively blocked. This enables the fabrication of a high-quality GaN HEMT epitaxy wafer with a threading dislocation density (TDD) of less than 10⁸/cm².

Second, as the TDD is significantly reduced, factors that degrade the device's electrical performance, such as leakage current and dynamic on-resistance, are eliminated, thereby maximizing the performance of the GaN switching power device.

Third, the lower defect density in the device improves the breakdown voltage characteristics, and the operational reliability at high electric fields and temperatures is greatly enhanced, extending the device's lifespan.

Fourth, by using an inexpensive and easily large-diameter scalable Si (111) substrate instead of expensive sapphire or SiC substrates, a highly cost-effective solution is provided for producing high-performance GaN power devices more economically.

### BRIEF DESCRIPTION OF DRAWINGS

FIG. 1 is a diagram showing the structure of a PSiS growth substrate wafer according to an embodiment of the present invention.

FIG. 2 is a diagram showing a modification of FIG. 1.

FIG. 3 is a diagram showing a structure where a GaN-based merged growth layer is formed using the PSiS growth substrate wafer of FIG. 1.

FIG. 4 is a diagram showing an epitaxy wafer in which a HEMT structure is stacked on the GaN-based merged growth layer of FIG. 3.

FIGS. 5 and 6 are diagrams showing modifications of FIG. 3.

### DETAILED DESCRIPTION

Hereinafter, preferred embodiments of the present invention will be described in detail with reference to the accompanying drawings.

The present invention includes several organically combined technical configurations to effectively control threading dislocations, a persistent problem in GaN-on-Si technology.

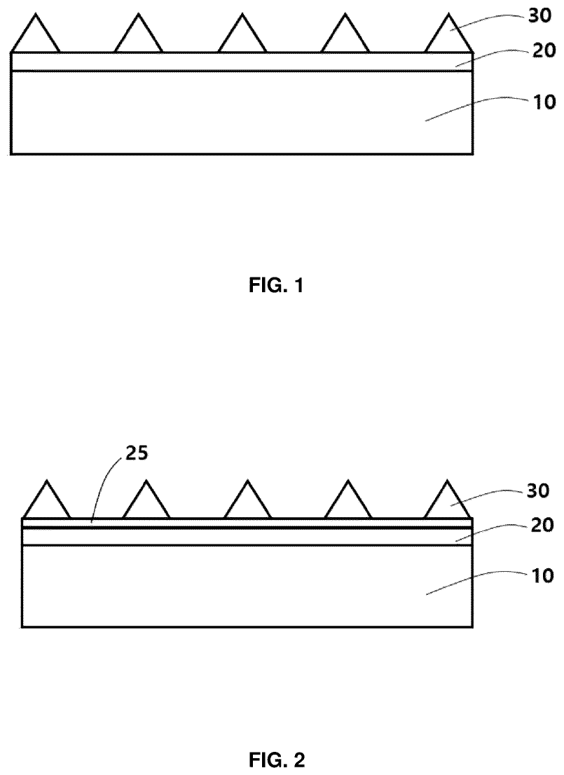

First, referring to FIGS. 1 and 2, the PSiS (Patterned Si Substrate) growth substrate, which is the core of the present invention, holds technical significance in that it provides a physical template that fundamentally blocks the propagation of threading dislocations rising from the Si substrate (10).

The plurality of SiOx protrusions (30) formed on the AlN nucleation layer (20) serve as a mask against threading dislocations, and the geometric shape of these protrusions (30) (e.g., dome, cone, etc.) optimizes the lateral growth dynamics of the GaN crystal during the subsequent ELOG (Epitaxial Lateral Overgrowth) process to induce defect-free merging.

Furthermore, by adding a SiNx protective film (25) to protect the AlN nucleation layer (20) during the SiOx protrusion (30) formation process, the quality of the initial GaN growth and process stability can be secured.

This has the effect of establishing an ideal foundation for high-quality GaN growth while using an inexpensive large-diameter Si substrate (10).

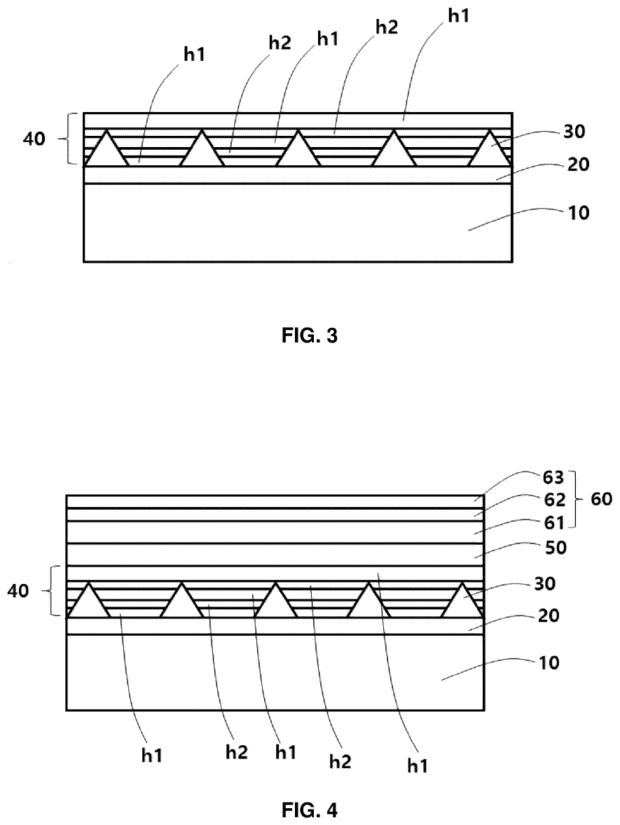

Next, referring to FIGS. 3 to 6, the epitaxy wafer completed by applying the ELOG method on the PSiS growth substrate (10) is significant as the final product of the present invention.

The ‘GaN-based merged growth layer (40)’ formed covering the SiOx protrusions (30) serves as a high-quality buffer layer with a dramatically reduced threading dislocation density.

In particular, process efficiency can be increased by configuring the merged growth layer (40) as a single uGaN layer with high material diffusivity, or an advanced technique can be implemented to filter even residual dislocations propagating laterally by applying a uGaN/AlN (or AlGaN) multilayer structure.

In addition to this, by introducing a second AlN nucleation layer (35) to improve growth uniformity and introducing an Al(z)Ga(1-z)N stress control layer (50) to solve the wafer bow problem in large-diameter wafers, the configuration ultimately has the effect of maximizing device characteristics and mass production yield.

The GaN HEMT device active layer (60) formed thereon exhibits excellent electrical characteristics thanks to the high-quality underlying structure.

Furthermore, the PSiS structure and Radial ELOG method proposed in the present invention use the principle wherein the SiOx protrusions act as a mask to block threading dislocations propagating vertically from the Si substrate, and secure high-quality, dislocation-free GaN regions through lateral growth, which are then merged. This allows the TDD of the entire epitaxy wafer to be dramatically lowered.

Hereinafter, embodiments according to the present invention will be described.

### Embodiment 1: Structure and Manufacture of PSiS Growth Substrate Wafer

Referring to FIG. 1, in step \textcircled{1}, a Si (111) wafer is prepared as the growth substrate (10).

The Si (111) substrate (10) is easily scaled to large diameters such as 4-inch, 6-inch, 8-inch, and 12-inch, and there is no particular restriction on its thickness.

Next, in step \textcircled{2}, a first AlN nucleation layer (20) is formed on the Si (111) substrate (10).

The AlN nucleation layer (20) plays an important role in suppressing the Si—Ga reaction (Melt-back Etching) that occurs when the Si substrate (10) and gallium (Ga) atoms react in a high-temperature hydrogen atmosphere during the subsequent GaN growth process.

The AlN nucleation layer (20) is preferably formed with a thickness of less than 0.5 μm using Chemical Vapor Deposition (CVD) methods such as MOCVD or HVPE, or it can be formed by combining Physical Vapor Deposition (PVD) methods like MBE or sputtering with a thermal treatment process.

Subsequently, in step \textcircled{3}, to form the protrusions (30) that will act as a mask for the ELOG process, an amorphous SiOx thin film is deposited.

The SiOx thin film is preferably deposited to a thickness of less than 2 μm using a PECVD or ALD process.

At this time, as shown in FIG. 2, to protect the AlN nucleation layer (20) from the subsequent dry etching process, a SiNx protective film (25) may be additionally introduced prior to the SiOx thin film deposition.

Finally, in step \textcircled{4}, a photolithography process and a dry etch process are used to selectively etch the SiOx thin film, thereby forming a plurality of SiOx protrusions (30) with a predetermined shape and arrangement.

This completes the PSiS growth substrate wafer according to the present invention.

The shape of the SiOx protrusions (30) can be designed in various forms such as Lens, Truncated, Dome, Cone, Polygon, Cubic, etc., which can induce lateral growth and effectively block threading dislocations during the ELOG process.

The positional arrangement of the SiOx protrusions (30) may primarily consider a Hexagonal structure.

The scale of the dimensions of the SiOx protrusions (30), such as size, pitch, height, etc., is preferably in the range from several micrometers to tens to hundreds of nanometers.

### Embodiment 2: Epitaxy Wafer Using PSiS Substrate (Multilayer Merged Growth Structure)

Referring to FIG. 3, the core of this embodiment is the formation of a GaN-based merged growth layer (40) with low TDD through a Radial ELOG process.

First, the growth of the GaN-based material starts on the exposed AlN nucleation layer (20) between the SiOx protrusions (30).

At this time, threading dislocations originate from the exposed AlN region, but as growth proceeds, the GaN crystal grows laterally, covering the SiOx protrusions (30) (Lateral Overgrowth).

The SiOx protrusions (30) act as a mask, blocking the vertical propagation of threading dislocations rising from below, and the laterally grown regions are formed as high-quality crystals with almost no threading dislocations.

As the lateral growth regions originating from neighboring protrusions (30) meet and merge, a flat GaN-based merged growth layer (40) with low TDD is completed across the entire wafer surface.

In the present invention, to maximize the TDD reduction effect, the GaN-based merged growth layer (40) can be formed as a multilayer structure of uGaN (undoped GaN) and AlN, as shown in FIG. 3.

For example, a uGaN layer (h1) of a predetermined thickness and a thin AlN layer (h2) of less than 5 nm are paired, and this pair is repeatedly deposited several times to grow above the height of the SiOx protrusions (30), achieving complete planarization.

uGaN has high material diffusivity, which is advantageous for lateral growth, and the thin AlN layer inserted in between serves to bend or annihilate remaining threading dislocations, further enhancing the TDD reduction efficiency.

Referring to FIG. 4, after the GaN-based merged growth layer (40) is formed flat, an Al(z)Ga(1-z)N stress control layer (50) can be additionally grown to control the wafer bow and overall stress as needed.

Finally, the final epitaxy wafer is completed by sequentially stacking the GaN HEMT device active layer (60), where the actual device operates, such as a GaN channel layer (61), an AlGaN barrier layer (62), and a p-GaN E-mode layer (63), on top.

Prior to forming the GaN HEMT device active layer (60) including the GaN channel layer (61), a high-resistance region can be formed as a single or multilayer film composed of GaN or AlN material, and in the case of GaN material, dopant components such as carbon (C) or iron (Fe) are intentionally introduced.

### Embodiment 3: Epitaxy Wafer Including a Second Nucleation Layer

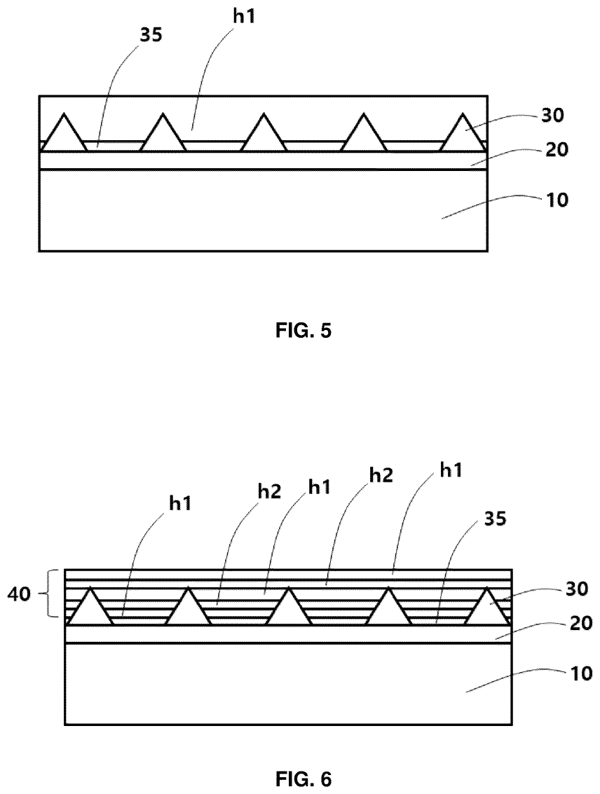

FIGS. 5 and 6 show another embodiment of the present invention.

This embodiment is mostly similar to Embodiment 2, but is characterized by the additional formation of a second nucleation layer (35) on the entire surface of the PSiS growth substrate before growing the GaN-based merged growth layer (40).

Specifically, a AlN thin film of less than 20 nm is deposited as the second nucleation layer (35) on the PSiS substrate where the SiOx protrusions (30) are formed.

The second nucleation layer (35) covers both the exposed first AlN nucleation layer (20) between the SiOx protrusions (30) and the surface of the SiOx protrusions (30), forming a continuous film.

Afterward, the ELOG process is performed using uGaN (FIG. 5) or a uGaN/AlN multilayer structure (FIG. 6).

The second nucleation layer (35) serves to control the initial nucleation conditions of GaN more uniformly across the entire wafer surface, enabling a more stable and reproducible ELOG process. The remaining process steps are the same as in Embodiment 2.

What is claimed is:

1. A growth substrate wafer for high-performance GaN switching power devices, comprising:
a Si growth substrate;
a first AlN nucleation layer formed on the Si growth substrate; and
a plurality of SiOx protrusions discontinuously spaced apart and arranged on the first AlN nucleation layer, wherein the surface of the first AlN nucleation layer is exposed in the regions between the plurality of SiOx protrusions, a growth substrate wafer for high-performance GaN switching power devices.

2. The growth substrate wafer of claim 1, wherein the shape of the SiOx protrusions is a Lens, Truncated, Dome, Cone, Polygon, or Cubic shape.

3. The growth substrate wafer of claim 1, further comprising a SiNx protective film formed between the first AlN nucleation layer and the plurality of SiOx protrusions.

4. An epitaxy wafer using the growth substrate wafer of any one of claim 1, comprising:
a GaN-based merged growth layer grown from the exposed surface of the first AlN nucleation layer between the plurality of SiOx protrusions, covering the top of the SiOx protrusions and merging with each other; and
a GaN HEMT device active layer formed on the GaN-based merged growth layer.

5. The epitaxy wafer of claim 4, wherein the GaN-based merged growth layer is a single layer of undoped GaN (uGaN).

6. The epitaxy wafer of claim 4, wherein the GaN-based merged growth layer is a multilayer structure in which uGaN layer and AlN layer or AlGaN layer are alternately stacked.

7. The epitaxy wafer of claim 4, further comprising an Al(z)Ga(1-z)N stress control layer formed between the GaN-based merged growth layer and the GaN HEMT device active layer.

8. The epitaxy wafer of claim 4, further comprising a second AlN nucleation layer formed between the plurality of SiOx protrusions and the GaN-based merged growth layer, and covering the exposed surface of the first AlN nucleation layer and the surface of the SiOx protrusions.

9. A method for manufacturing an epitaxy wafer using a growth substrate wafer for high-performance GaN switching power devices, comprising the steps of:
(a) preparing a Si growth substrate;
(b) forming a first AlN nucleation layer on the Si growth substrate;
(c) depositing a SiOx thin film on the first AlN nucleation layer;
(d) patterning the SiOx thin film to form a plurality of discontinuously spaced SiOx protrusions;
(e) forming a GaN-based merged growth layer by laterally growing (Epitaxial Lateral Overgrowth, ELOG) a GaN-based material from the first AlN nucleation layer exposed between the SiOx protrusions and merging them over the SiOx protrusions; and
(f) stacking a GaN HEMT device active layer on the GaN-based merged growth layer.

10. The method of claim 9, wherein said step (e) comprises forming the GaN-based merged growth layer by alternately and repeatedly growing uGaN layer and one of AlN layer and AlGaN layer.

11. The method of claim 9, further comprising a step of forming a second AlN nucleation layer on the first AlN nucleation layer and the plurality of SiOx protrusions, between said step (d) and step (e).
